(19) United States
(12) Patent Application Publication
(10) Pub. No.: US 2026/0161096 A1
(43) Pub. Date: Jun. 11, 2026

(54) PROJECTION EXPOSURE APPARATUS FOR SEMICONDUCTOR LITHOGRAPHY AND METHOD

(71) Applicant: Carl Zeiss SMT GmbH, Oberkochen (DE)

(72) Inventors: Joachim HARTJES, Aalen (DE); Bettina WEHLAUCH, Nattheim (DE); Andreas RABA, Niederschoenenfeld (DE); Johannes LIPPERT, Buch am Wald (DE); Erik LOOPSTRA, Ederheim Huernheim (DE)

(21) Appl. No.: 19/182,182

(22) Filed: Apr. 17, 2025

Related U.S. Application Data
(63) Continuation of application No. PCT/EP2023/079125, filed on Oct. 19, 2023.

(30) Foreign Application Priority Data
Oct. 24, 2022 (DE) 10 2022 211 226.1

(51) Int. Cl. G03F 7/00

(52) U.S. Cl. CPC G03F 7/70266; G03F 7/70825

(57) ABSTRACT

A projection exposure apparatus for semiconductor lithography, comprising at least one optical element. At least one actuator for deforming an optically effective surface of the optical element is arranged on a back side of the optical element. The actuator is configured to exert compressive or tensile forces on the optical element perpendicular to the optically effective surface. The at least one actuator is in a cutout in a main body of the optical element. A method for fixing an actuator in a cutout in a main body of an optical element, which method comprises: providing the actuator and at least one radial clamping element; inserting the actuator and the radial clamping element into the cutout, wherein the radial clamping element is arranged between the actuator and an inner surface of the cutout; and bracing the clamping element for the purpose of fixing the actuator.

### CROSS-REFERENCE TO RELATED APPLICATIONS

The present application is a continuation of, and claims benefit under 35 USC 120 to, international application No. PCT/EP2023/079125, filed Oct. 19, 2023, which claims benefit under 35 USC 119 of German Application No. 10 2022 211 226.1, filed Oct. 24, 2022. The entire disclosure of each of these applications is incorporated by reference herein.

### FIELD

The disclosure relates to a projection exposure apparatus for semiconductor lithography, having optical elements that are provided with actuators, and to a method for integrating the actuators.

### BACKGROUND

Projection exposure apparatuses for semiconductor technology are used for producing extremely fine structures, such as on semiconductor components or other microstructured components. An operating principle of the apparatuses can be based on the production of very fine structures down to the nanometre range by way of generally size-reducing imaging of structures on a mask, using what is referred to as a reticle, on an element to be structured that is referred to as a wafer and provided with photosensitive material. The minimum dimensions of the structures produced are generally directly dependent on the wavelength of the light used. In addition to the predominantly used light sources having an emission wavelength in a range from 100 nanometres (nm) to 300 nm, in the so-called DUV range, light sources with an emission wavelength of the order of a few nanometres, for example between 1 nm and 120 nm, such as of the order of 13.5 nm, have found increased use in recent times. The described wavelength range is also referred to as the EUV range.

The optical elements used for imaging for the above-described application are positioned with the greatest reasonably obtainable precision and/or optionally also are deformed in order for it to be possible to ensure sufficient imaging quality. For example, optical elements that take the form of mirrors are not only positioned with up to six degrees of freedom but also configured to allow the optically effective surface to be deformed. The optically effective surface is that the surface of an optical element on which radiation used for imaging and exposure is incident during the normal operation of the associated apparatus.

In this case, the deformation is brought about by actuators arranged on the back side of the mirror opposite to the optically effective surface. In the process, the utilized actuators may in principle act on the optical element in a manner parallel to the optically effective surface but also in a manner perpendicular thereto. A corresponding arrangement is disclosed in the German patent application DE 10 2020 210 773 A1. The mentioned document discloses an optical element, in which actuators act on the optical element from the back side of the optical element, i.e. from the side opposite to the optically effective surface, and introduce forces in a manner perpendicular to the optically effective surface. According to the teaching of the mentioned document, a back plate is used as a counter bearing, on which the actuators are supported. However, a consequence of using the back plate is that the actuators are not optimally accessible for maintenance or repair purposes.

### SUMMARY

The present disclosure seeks to provide an improved device and an improved method.

In an aspect, the disclosure provides a projection exposure apparatus for semiconductor lithography which comprises at least one optical element, wherein at least one actuator for deforming an optically effective surface of the optical element is arranged on a back side of the optical element. In this case, the actuator is configured to exert compressive or tensile forces on the optical element in a manner perpendicular to the optically effective surface. According to the disclosure, the at least one actuator is arranged in a cutout in a main body of the optical element.

In this context, the actuator may be connected to the main body by way of a bearing contact surface arranged in the cutout. For example, the aforementioned connection of the actuator to the main body can help allow absorption of the forces that on account of the elastic properties of the material of the optical element act on the actuator during an actuation thereof. In other words, the main body itself acts as a counter bearing for the actuator and there is no need for the provision of a back plate as has been used in the art.

In an embodiment of the disclosure, the optical element comprises an intermediate body arranged between an optics body and the main body. In this case, the optics body is that part of the optical element which comprises the optically effective surface. The intermediate body now offers the possibility of introducing further functionalities into the optical element.

Thus, there might be at least one cavity for at least a sectional mechanical decoupling of the optics body from the main body present between the main body and the optics body; for example, this may be achieved by an appropriate design of the intermediate body.

For example, the at least one cavity may be arranged between the intermediate body and the main body.

The at least one actuator may extend at least in part into the aforementioned cavity; it is likewise conceivable that the at least one cavity has an enclosed embodiment vis-à-vis the at least one actuator. In the latter case, due to the enclosed embodiment of the cavity is that, should the actuators be removed and cleaning be performed with water for example, cleaning fluid is unable to enter the cavity, and so there is no longer the need to dry the cavity before the actuators are mounted.

A further desirable implication of the use of an intermediate body is that the intermediate body may comprise fluid channels for the temperature control of the optical element. It is desirable here that an intermediate body may be better accessible for processing, such as for the creation of the aforementioned fluid channels, than for example an optics body or the main body.

Certain mechanical decoupling perpendicular to the effective direction of the actuator may be obtained by virtue of the fact that a pin may be present on the base of the cutout, for example on the intermediate body, the pin being mechanically connected to the actuator by way of an effective contact surface. Transverse deformations that occur during an operation of the actuator are absorbed by the pin in this case and are not transferred into the vicinity of the optically effective surface.

What can be achieved as a result of the distance between the optically effective surface and the effective contact surface being between 5 mm and 20 mm is that a deformation of the optically effective surface can be achieved with comparatively low actuator forces.

In a variant of the disclosure, the bearing contact surface may be formed on a shoulder in the cutout. In this case, for example, the bearing contact surface may easily be connected to the actuator by way of an adhesive connection.

Particularly good accessibility of the bearing contact surface, for example for the application of an adhesive, may be achieved by virtue of the fact that the distance between the bearing contact surface and the back side of the main body is between 0 millimetre (mm) and 500 mm, such as between 0 mm and 250 mm, for example between 50 mm and 150 mm.

At least one clamping element may be arranged between the actuator and an inner surface of the cutout in a variant of the disclosure. In this context, a clamping element should be understood to mean, for example, an element suitable for bracing the actuator in the cutout by way of clamping forces.

In this context, the clamping element may be formed as a sleeve-shaped body for example. In this case, the outer surface of the clamping element may be braced against an inner surface of the cutout and the inner surface of the clamping element may be braced against an outer surface of the actuator, and a frictional connection may thus be established.

A particularly effective and also reversible connection between the actuator and the main body may be established by virtue of the clamping element comprising a shape memory alloy. In this context, the property of shape memory alloys of applying large forces already in small volumes comes to bear.

In an aspect, the disclosure provides a method according to the disclosure for fixing an actuator in a cutout in a main body of an optical element, which method comprises the following steps:
providing the actuator and at least one radial clamping element,
inserting the actuator and the radial clamping element into the cutout, wherein the radial clamping element is arranged between the actuator and an inner surface of the cutout, and
bracing the clamping element for the purpose of fixing the actuator.

In this context, the clamping element may be braced for example by changing the temperature of the main body or of the clamping element.

Comparatively large forces may be realized by the temperature change should the clamping element comprise a shape memory alloy.

What may be achieved by virtue of, prior to the bracing of the clamping element, the actuator being pressed with a defined contact force in the direction of an optically effective surface is that a possible play between the actuator and the optics body or the intermediate body is minimized or even completely eliminated, and so this may be referred to as a connection of the actuator without play.

### BRIEF DESCRIPTION OF THE DRAWINGS

Exemplary embodiments and variants of the disclosure are explained in detail below on the basis of the drawing. In the drawings:

FIG. 1 schematically shows a meridional section of a projection exposure apparatus for EUV projection lithography;

FIG. 2 schematically shows a meridional section of a projection exposure apparatus for DUV projection lithography;

FIG. 3 shows an embodiment of an optical element according to the disclosure;

FIG. 4 shows an embodiment of an optical element according to the disclosure; and

FIG. 5 shows an embodiment of an optical element according to the disclosure.

### DETAILED DESCRIPTION

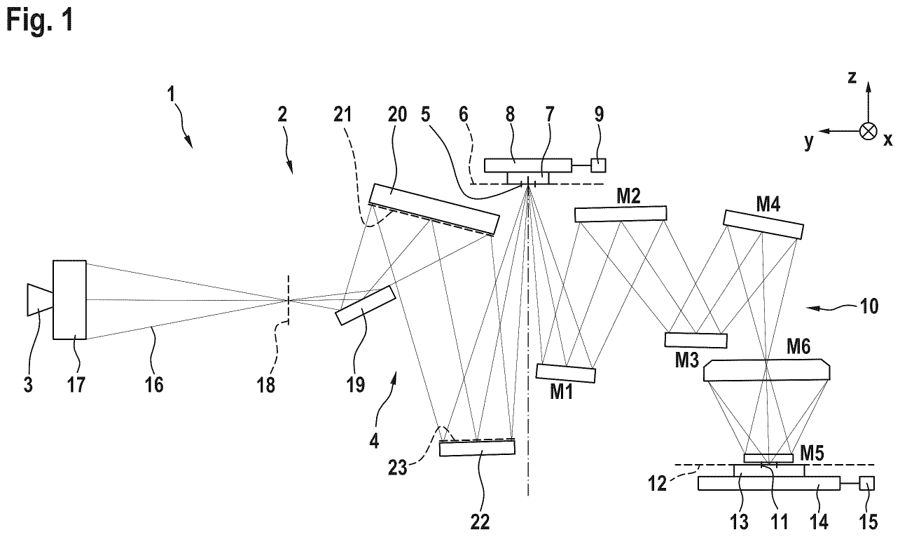

In the following text, certain constituent parts of a microlithographic projection exposure apparatus 1 are described in exemplary fashion, initially with reference to FIG. 1. The description of the basic structure of the projection exposure apparatus 1 and of its constituent parts are to be understood as non-limiting.

One embodiment of an illumination system 2 of the projection exposure apparatus 1 has, in addition to a radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9, in particular in a scanning direction.

A Cartesian xyz-coordinate system is depicted in FIG. 1 for explanation purposes. The x-direction runs perpendicularly to the plane of the drawing into the latter. The y-direction runs horizontally, and the z-direction runs vertically. The scanning direction runs in the y-direction in FIG. 1. The z-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. In an alternative, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular in the y-direction. The displacement, firstly, of the reticle 7 by way of the reticle displacement drive 9 and, secondly, of the wafer 13 by way of the wafer displacement drive 15 may be synchronized with one another.

The radiation source 3 is an EUV radiation source. The radiation source 3 emits in particular EUV radiation 16, which is also referred to below as used radiation, illumination radiation or illumination light. The used radiation has in particular a wavelength in the range of between 5 nm and 30 nm. The radiation source 3 may be a plasma source, for example a laser-produced plasma (LPP) source or a gas discharge-produced plasma (GDPP) source. It may also be a synchrotron-based radiation source. The radiation source 3 may be a free electron laser (FEL).

The illumination radiation 16 emanating from the radiation source 3 is focused by a collector 17. The collector 17 may be a collector having one or more ellipsoidal and/or hyperboloidal reflection surfaces. The illumination radiation 16 may be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, comprising the radiation source 3 and the collector 17, and the illumination optical unit 4.

The illumination optical unit 4 comprises a deflection mirror 19 and, disposed downstream thereof in the beam path, a first facet mirror 20. The deflection mirror 19 may be a plane deflection mirror or, in an alternative to that, a mirror with a beam-influencing effect going beyond the pure deflection effect. In an alternative to that or in addition, the deflection mirror 19 may be in the form of a spectral filter that separates a used light wavelength of the illumination radiation 16 from extraneous light at a different wavelength. Should the first facet mirror 20 be arranged in a plane of the illumination optical unit 4 which is optically conjugate to the object plane 6 as a field plane, this facet mirror is also referred to as a field facet mirror. The first facet mirror 20 comprises a multiplicity of individual first facets 21, which are also referred to below as field facets. FIG. 1 illustrates only some of the facets 21 by way of example.

The first facets 21 may take the form of macroscopic facets, in particular rectangular facets or facets with an arc-shaped edge contour or an edge contour of part of a circle. The first facets 21 may take the form of plane facets or, in an alternative to that, convexly or concavely curved facets.

As is known for example from DE 10 2008 009 600 A1, the first facets 21 themselves may each also be composed of a multiplicity of individual mirrors, in particular a multiplicity of micromirrors. The first facet mirror 20 may take the form of a microelectromechanical system (MEMS system) in particular. For details, reference is made to DE 10 2008 009 600 A1.

The illumination radiation 16 travels horizontally, i.e. in the y-direction, between the collector 17 and the deflection mirror 19.

In the beam path of the illumination optical unit 4, a second facet mirror 22 is disposed downstream of the first facet mirror 20. Should the second facet mirror 22 be arranged in a pupil plane of the illumination optical unit 4, this facet mirror is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or alternatively may be facets composed of micromirrors. In this regard, reference is likewise made to DE 10 2008 009 600 A1.

The second facets 23 may have plane reflection surfaces or, in an alternative to that, convexly or concavely curved reflection surfaces.

The illumination optical unit 4 thus forms a doubly faceted system. This fundamental principle is also referred to as a fly's eye condenser (fly's eye integrator).

It may be desirable to arrange the second facet mirror 22 not exactly in a plane that is optically conjugate to a pupil plane of the projection optical unit 10. In particular, the pupil facet mirror 22 may be arranged so as to be tilted relative to a pupil plane of the projection optical unit 10, as described for example in DE 10 2017 220 586 A1.

The individual first facets 21 are imaged into the object field 5 with the aid of the second facet mirror 22. The second facet mirror 22 is the last beam-shaping mirror or actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror or, in an alternative to that, two or more mirrors, which are arranged one behind another in the beam path of the illumination optical unit 4. The transfer optical unit may in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20 and the pupil facet mirror 22.

In a further embodiment of the illumination optical unit 4, the deflection mirror 19 may also be omitted, and so the illumination optical unit 4 may then have exactly two mirrors downstream of the collector 17, specifically the first facet mirror 20 and the second facet mirror 22.

The imaging of the first facets 21 into the object plane 6 via the second facets 23, or using the second facets 23, and a transfer optical unit is generally only an approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or a different number of mirrors Mi are also possible. The penultimate mirror M5 and the last mirror M6 each have a passage opening for the illumination radiation 16. The projection optical unit 10 is a doubly obscured optical unit. The projection optical unit 10 has an image-side numerical aperture which is greater than 0.5 and may also be greater than 0.6 and might be for example 0.7 or 0.75.

Reflection surfaces of the mirrors Mi may be in the form of free-form surfaces without an axis of rotational symmetry. In an alternative to that, the reflection surfaces of the mirrors Mi may be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, in particular with alternating layers of molybdenum and silicon.

The projection optical unit 10 has a large object-image shift in the y-direction between a y-coordinate of a centre of the object field 5 and a y-coordinate of the centre of the image field 11. In the y-direction, this object-image shift may be of approximately the same size as a z-distance between the object plane 6 and the image plane 12.

In particular, the projection optical unit 10 may have an anamorphic design. In particular, it has different imaging scales βx, βy in the x- and y-directions. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x- and y-directions, for example with absolute values of 0.125 or 0.25, are also possible.

The number of intermediate image planes in the x-direction and in the y-direction in the beam path between the object field 5 and the image field 11 may be the same or may be different, depending on the embodiment of the projection optical unit 10. Examples of projection optical units with different numbers of such intermediate images in the x- and y-directions are known from US 2018/0074303 A1.

In each case, one of the pupil facets 23 is assigned to exactly one of the field facets 21 for the purpose of forming a respective illumination channel for illuminating the object field 5. This may in particular result in illumination according to the Köhler principle. The far field is decomposed into a multiplicity of object fields 5 with the aid of the field facets 21. The field facets 21 create a plurality of images of the intermediate focus on the pupil facets 23 in each case assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It can have a uniformity error of less than 2%. Field uniformity may be achieved by overlaying different illumination channels.

The illumination of the entrance pupil of the projection optical unit 10 may be defined geometrically by way of an arrangement of the pupil facets. The intensity distribution in the entrance pupil of the projection optical unit 10 may be set by selecting the illumination channels, in particular the subset of the pupil facets which guide light. This intensity distribution is also referred to as illumination setting.

A likewise preferred pupil uniformity in the region of portions of an illumination pupil of the illumination optical unit 4 which are illuminated in a defined manner may be achieved by a redistribution of the illumination channels.

Further aspects and details of the lighting of the object field 5 and in particular of the entrance pupil of the projection optical unit 10 are described hereinafter.

The projection optical unit 10 may have a homocentric entrance pupil in particular. The latter may be accessible. It may also be inaccessible.

The entrance pupil of the projection optical unit 10 generally cannot be illuminated exactly via the pupil facet mirror 22. The aperture rays often do not intersect at a single point in the event of imaging by the projection optical unit 10 that telecentrically images the centre of the pupil facet mirror 22 onto the wafer 13. However, it is possible to find an area in which the spacing of the aperture rays, which is determined in pairs, becomes minimal. This area represents the entrance pupil or an area in real space conjugate thereto. In particular, this area exhibits a finite curvature.

It may be the case that the projection optical unit 10 has different positions of the entrance pupil for the tangential beam path and for the sagittal beam path. In this case, an imaging element, in particular an optical structural element of the transfer optical unit, should be provided between the second facet mirror 22 and the reticle 7. Using this optical element, the different positions of the tangential entrance pupil and the sagittal entrance pupil may be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged with a tilt in relation to the object plane 6. The first facet mirror 20 is arranged so as to be tilted with respect to an arrangement plane defined by the deflection mirror 19.

The first facet mirror 20 is arranged with a tilt in relation to an arrangement plane defined by the second facet mirror 22.

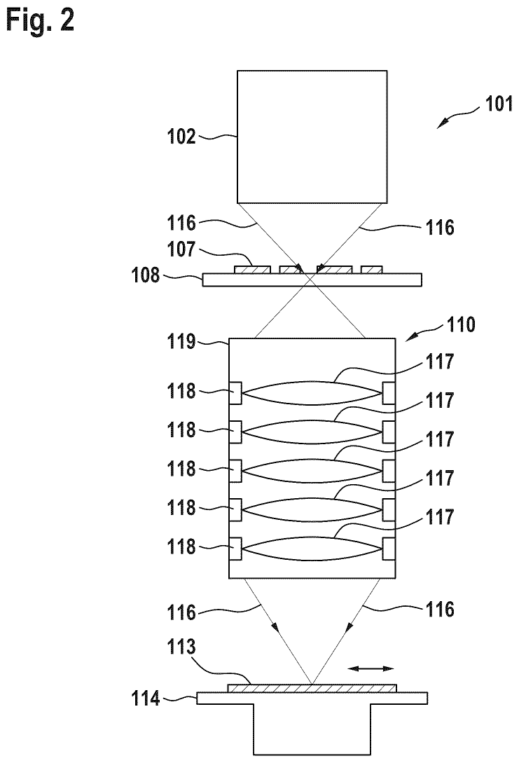

FIG. 2 schematically shows a meridional section through a further projection exposure apparatus 101 for DUV projection lithography, in which the disclosure can likewise be used.

The structure of the projection exposure apparatus 101 and the principle of the imaging are comparable with the structure and procedure described in FIG. 1. Identical component parts are denoted by a reference sign increased by 100 with respect to FIG. 1, i.e. the reference signs in FIG. 2 start at 101.

In contrast with an EUV projection exposure apparatus 1 as described in FIG. 1, refractive, diffractive and/or reflective optical elements 117, such as lens elements, mirrors, prisms, terminating plates, and the like, may be used for imaging or for illumination in the DUV projection exposure apparatus 101 on account of the greater wavelength of the DUV radiation 116, utilized as used light, in the range from 100 nm to 300 nm, in particular of the order of 193 nm. The projection exposure apparatus 101 in this case substantially comprises an illumination system 102, a reticle holder 108 for receiving and exactly positioning a reticle 107 which is provided with a structure and determines the later structures on a wafer 113, a wafer holder 114 for holding, moving, and exactly positioning this very wafer 113, and a projection lens 110, with multiple optical elements 117 held by way of mounts 118 in a lens housing 119 of the projection lens 110.

The illumination system 102 provides DUV radiation 116 used for imaging the reticle 107 on the wafer 113. A laser, a plasma source or the like may be used as the source of this radiation 116. The radiation 116 is shaped in the illumination system 102 via optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the structure of the downstream projection optical unit 101 with the lens housing 119 does not differ in principle from the structure described in FIG. 1 and is therefore not described in further detail.

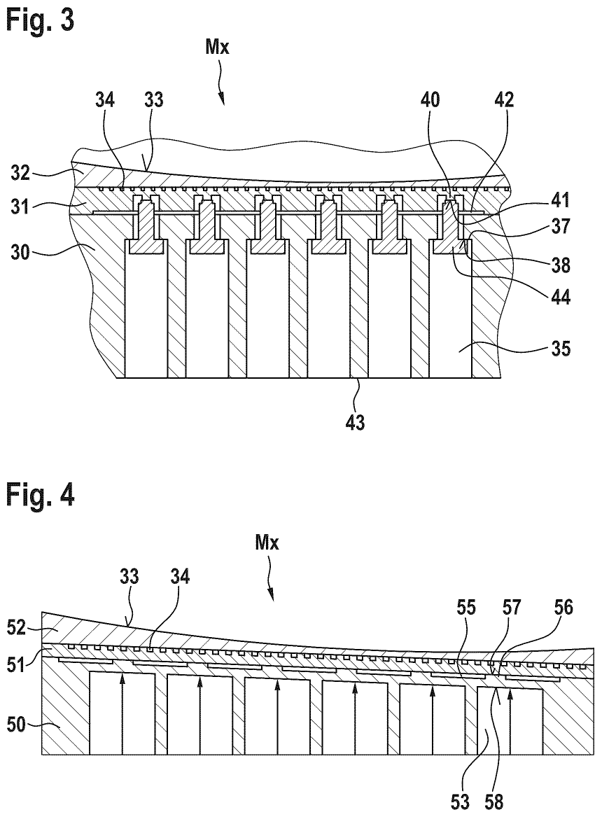

FIG. 3 shows a first embodiment of an optical element according to the disclosure, as finds use in the projection exposure apparatuses 1, 101 that are described in FIG. 1 and FIG. 2. In the example shown, the optical element takes the form of a deformable mirror Mx. The mirror Mx comprises a main body 30, an intermediate body 31 and an optics body 32, with the optically effective surface 33, on which used radiation, i.e. radiation used for imaging and exposure, is incident during the operation of the associated projection exposure apparatus 1, 101, being formed on the optics body. In the embodiment depicted in FIG. 3, the intermediate body 31 comprises fluid channels 34 for the temperature control of the mirror Mx and a cutout in the direction of the main body such that a cavity in the form of a decoupling pocket 42 and serving for sectional mechanical decoupling between the intermediate body 31 and the main body 30 is formed, whereby improved options for deforming the optically effective surface 33 arise. For example, the three bodies 30, 31, 32 may be connected to one another by bonding, with other connection technologies also being conceivable. The multi-part structure of the mirror Mx is desirable in that—as explained above—functional structures such as the fluid channels 34, for example, may be realized more easily from a manufacturing point of view. Cutouts which take the form of drilled holes 35 and in which actuators 44 for deforming the optically effective surface 33 of the mirror Mx are introduced are disposed in the main body 30, on the back side 43 opposite the optically effective surface 33. The drilled holes 35 comprise a shoulder 37, which represents the transition from an initially larger bore diameter to a smaller bore diameter of the drilled hole 35. The shoulder 37 comprises a first bearing contact surface 38, on which the actuator 44 with a corresponding contact surface is connected to the main body 30. The drilled hole 35 reaches into the intermediate body 31, wherein a pin 40 with an effective contact surface 41 for connecting a further contact surface of the actuator 44 is formed on the base of the drilled hole. The pin 40 serves for mechanical decoupling, for example in cases in which there is an adhesive bond between the actuator 44 and the intermediate body 31. In these cases, the pin 40 absorbs for example lateral stresses, and so there is no deformation of the optically effective surface 33 on account of these stresses, or the influence of the latter is reduced. The tolerance chain of the individual features that determine the position, for example the effective contact surface 41 of the pin 40 or the bearing contact surface 38 of the shoulder 37, is designed such that an adhesive connection at the pin 40 may have a minimal thickness. The tolerances are compensated for by way of an adhesive connection arranged between actuator 44 and shoulder 37. In an alternative, the tolerances may also be compensated for by way of what are known as spacers, i.e. washers manufactured with a predetermined thickness. A substantial feature of arranging the actuators 44 in drilled holes 35 starting from the back side 43 of the mirror consists in the fact that the actuators 44 can be detached from the mirror Mx and be replaced with justifiable outlay at all times, for example by local heating of the adhesive connections. In this case, to protect a coating formed on the optically effective surface 33, a temperature-controlled medium may flow through the fluid channels 34 formed in the intermediate body 31 while the adhesive connections are heated.

The connection of the actuators 44 to the mirror Mx may be varied by varying a plurality of parameters. For example, the distance between the effective contact surface 41 of the pin 40 and the optically effective surface 33 may be varied; the distance may be in a range of 5 mm to 20 mm, depending on design. To facilitate a replacement of an actuator 44, the adhesive connection of the actuators 44 to the bearing contact surface 38 of the shoulder 37 may be arranged as close as possible to the back side 43 of the main body 30, in order to improve the reachability. The position of the fluid channels 34 in the intermediate body 31 may likewise be varied, depending on the thermal load on account of the absorption of used light by way of the optically effective surface 33 and waste heat of the actuators 44. It is also conceivable that the fluid channels 34 adopt the function of the decoupling pocket 42.

FIG. 4 shows a further embodiment of an optical element in the form of a mirror Mx, the embodiment comprising a main body 50, an intermediate body 51 and an optics body 52 with an optically effective surface 33. The main body 50 comprises cutouts in the form of drilled holes 53 with a constant bore diameter and a flat base 58. Cavities in the form of decoupling pockets 55 and pins 56 for decoupling the lateral forces, as already explained in relation to FIG. 3, are formed on the side of the main body 50 facing the intermediate body 51. In the example shown, the effective contact surface 57 of the pins 56 acts directly on the lower side of the intermediate body 51 facing the main body 50. The effective direction of the actuators (not depicted in the figure) is represented in the form of arrows. The actuators are connected to the main body 50 by way of the base 58 of the drilled hole 53. On account of the arrangement as explained in relation to FIG. 4, the decoupling pockets 55 are completely closed. In cases in which the mirror Mx is cleaned for example from its back side, a cleaning medium cannot reach the decoupling pockets 55, and so cleaning overall is simplified. There is also no need to clean the decoupling pockets 55 on account of their enclosed embodiment. Furthermore, the distance between the pins 56 and the optically effective surface 33 may be further reduced as a result of the embodiment of the decoupling pockets 55 shown in the figure; this may be desirable, depending on the design.

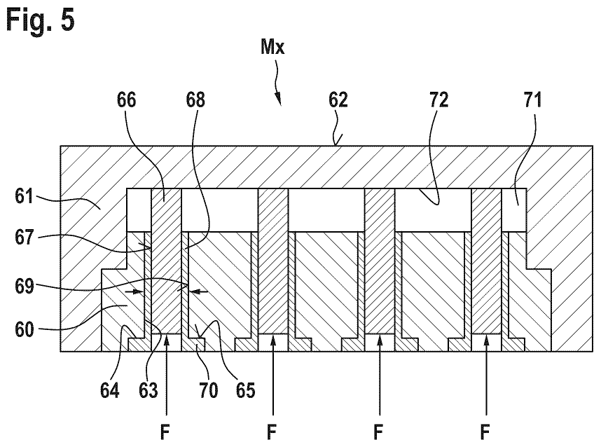

FIG. 5 shows a further embodiment of the disclosure, in which the mirror Mx comprises a main body 60 and an optics body 61 with an optically effective surface 62. A cavity as a decoupling pocket 71 is formed between the main body 60 and the optics body 61. Once again, the main body 60 comprises drilled holes 63 with shoulders 64, in which sleeves 68 produced from shape memory alloys (SMA) are arranged as clamping elements. To prepare the mounting of actuators 66, the sleeves 68 are pushed into the drilled holes 63 until the sleeve contact surfaces 65 of edges 70 of the sleeves 68 that correspond to the shoulders 64 of the drilled holes 63 rest against the shoulder 64. In this case, the sleeves 68 are in an opened operational state. Subsequently, the actuators 66 are inserted into the sleeves 68 and pressed with a defined contact force F, represented as an arrow in FIG. 5, against the back side 72 of the optics body 61 opposite the optically effective surface 62, whereby it is possible to ensure a connection without play between the actuators 66 and the optics body 61. Once the contact force F is applied, the conversion of the microstructure of the material of the sleeves 68 is activated, for example by heating, and the sleeves are thereby brought into a closed operational state. By way of the sleeves 68, the outer surfaces 67 of the actuators 66 are thereby securely connected by clamping to the inner surfaces 69, serving as bearing contact surfaces, of the drilled holes 63 in the main body 60. To detach the connections, the sleeves 68 can be brought back into the opened operational state by heating and a renewed modification of the microstructure of the material of the sleeves 68 caused thereby. A feature of using sleeves 68 made of a shape memory alloy is that the sleeves 68 may be reused and comparatively fast mounting is possible as a result of the direct switching of the sleeve 68 from an opened operational state to a closed operational state. Furthermore, shape memory alloys have significantly lower long-term drifts and virtually no ageing. Moreover, in comparison with other possible connection elements, for example piezo-active or magnetostrictive actuators, the shape memory alloy is distinguished by a high volume-specific work capacity. This leads to using very little space for fixing the actuator 66. In principle, the integration of a fluid channel 34, as explained in relation to FIG. 3 and FIG. 4, is also possible in the embodiment depicted in FIG. 5. In an alternative, use can also be made of what is known as a one-way shape memory alloy, which, once activated, clamps the actuator 66 in the drilled hole 63 but can no longer be opened by being heated a second time. In that case, the sleeve 68 can only be opened or removed mechanically. There still is the feature of using little space, as explained above.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Main body
31 Intermediate body
32 Optics body
33 Optically effective surface
34 Fluid channel
35 Drilled hole
37 Shoulder
38 Contact surface of the shoulder
40 Pin
41 Contact surface of the pin
42 Decoupling pocket
43 Back side of the main body
44 Actuator
50 Main body
51 Intermediate body
52 Optics body
53 Drilled hole
55 Decoupling pocket
56 Pin
57 Contact surface of the pin
58 Base of the drilled hole
60 Main body
61 Optics body
62 Optically effective surface
63 Drilled hole
64 Shoulder of the drilled hole
65 Contact surface of the SMA sleeve
66 Actuator
67 Outer surface of the actuator
68 SMA sleeve
69 Inner surface of the main body
70 Edge
71 Decoupling pocket
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors
F Contact force prior to fixing

What is claimed is:

1. An apparatus, comprising:
an optical element comprising an optically effective surface, a main body having a cutout, an optics body and a back side; and
an actuator configured to deform the optically effective surface of the optical element, the actuator being disposed at the back side of the optical element,
wherein:
the actuator is configured to exert compressive or tensile forces on the optical element in a manner perpendicular to the optically effective surface;
the actuator is in the cutout in the main body of the optical element;
a cavity is present between the main body of the optical element and the optics body of the optical element;
the cavity is configured to at least a sectionally mechanically decouple of the optics body of the optical element from the main body of the optical element;
the actuator at least partially extends into the cavity;
the cutout in the main body of the optical has a bearing surface;
the actuator is connected to the main body via the bearing surface in the cutout of the main body of the optical element; and
the apparatus is a semiconductor lithography projection exposure apparatus.

2. The apparatus of claim 1, wherein the optical element further comprises an intermediate body between the optics body and the main body.

3. The apparatus of claim 2, wherein the cavity is between the intermediate body and the main body.

4. The apparatus of claim 2, wherein the intermediate body comprises fluid channels configured to control a temperature of the optical element.

5. The apparatus of claim 1, wherein the bearing surface is on a shoulder in the cutout.

6. The apparatus of claim 1, further comprising an adhesive connection connecting the bearing surface to the actuator.

7. The apparatus of claim 6, wherein a distance between the bearing contact surface and the back side of the main body is between 0 mm and 500 mm.

8. The apparatus of claim 1, further comprising a clamping element between the actuator and an inner surface of the cutout.

9. The apparatus of claim 8, wherein the clamping element comprises a sleeve-shaped body.

10. The apparatus of claim 8, wherein the clamping element comprises a shape memory alloy.

11. The apparatus of claim 1, further comprising a pin at a base of the cutout, wherein the pin is mechanically connected to the actuator via an effective contact surface of the pin.

12. An apparatus, comprising:
an optical element comprising an optically effective surface, a main body having a cutout, an optics body and a back side;
an actuator configured to deform the optically effective surface of the optical element, the actuator being disposed at the back side of the optical element; and
a pin at the base of the cutout of the optical element,
wherein:
the actuator is configured to exert compressive or tensile forces on the optical element in a manner perpendicular to the optically effective surface;
the actuator is in the cutout in the main body of the optical element;
a cavity is present between the main body of the optical element and the optics body of the optical element;
the cavity is configured to at least a sectionally mechanically decouple of the optics body of the optical element from the main body of the optical element;
the actuator at least partially extends into the cavity; and
the pin is mechanically connected to the actuator via an effective contact surface of the pin; and
the apparatus is a semiconductor lithography projection exposure apparatus.

13. The apparatus of claim 12, wherein the optical element further comprises an intermediate body between the optics body and the main body, and the pin is on the intermediate body.

14. The apparatus of claim 12, wherein a distance between the optically effective surface and the effective contact surface is between 5 millimetres (mm) and 20 mm.

15. The apparatus of claim 12, wherein the optical element further comprises an intermediate body between the optics body and the main body.

16. The apparatus of claim 15, wherein the cavity is between the intermediate body and the main body.

17. A method for fixing an actuator in a cutout in a main body of an optical element, the method comprising:
inserting the actuator and a radial clamping element into the cutout in the main body of the optical element so that the radial clamping element is between the actuator and an inner surface of the cutout in the main body of the optical element; and
bracing the clamping element to fix the actuator in the cutout in the main body of the optical element.

18. The method of claim 17, wherein bracing the clamping element comprises changing a temperature of the main body of the optical element or changing a temperature of the clamping element.

19. The method of claim 18, wherein the clamping element comprises a shape memory alloy.

20. The method of claim 18, further comprising, before bracing the clamping element, pressing the actuator with a defined contact force in the direction of an optically effective surface of the optical element.
